(19) United States
(12) Patent Application Publication
(10) Pub. No.: US 2023/0282786 A1
(43) Pub. Date: Sep. 7, 2023

(54) ENCAPSULATION ARRANGEMENTS IN LIGHT-EMITTING DIODE PACKAGES

(71) Applicant: CreeLED, Inc., Durham, NC (US)

(72) Inventors: Joseph M. Favale, JR., Cary, NC (US); Robert David Schmidt, Wake Forest, NC (US)

(21) Appl. No.: 17/686,943

(22) Filed: Mar. 4, 2022

(51) Int. Cl. H01L 33/54; H01L 33/62; H01L 33/58; H01L 25/075

(52) U.S. Cl. CPC H01L 33/54; H01L 33/62; H01L 33/58; H01L 25/0753

(57) ABSTRACT

Light-emitting diode (LED) packages and more particularly encapsulation arrangements in LED packages that provide reduced internal stresses are disclosed. LED packages may include housings that form a recess with one or more LED chips provided within the recess. Encapsulation arrangements include multiple encapsulation layers where a first encapsulation layer covers portions of a recess floor and sidewalls of the one or more LED chips, and a second encapsulation layer that covers the first encapsulation layer. In this manner, the first encapsulation layer is configured to buffer internal encapsulation stresses during operation that could lead to delamination of the LED chips.

### FIELD OF THE DISCLOSURE

The present disclosure relates to light-emitting diode (LED) packages, and more particularly to encapsulation arrangements in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions.

LED packages have been developed that can provide mechanical support, electrical connections, and encapsulation for LED emitters. Lumiphoric materials, such as phosphors, may also be arranged in close proximity to LED emitters to convert portions of light emissions to different wavelengths. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) packages, and more particularly to encapsulation arrangements in LED packages that provide reduced internal stresses. LED packages may include housings that form a recess with one or more LED chips provided within the recess. Encapsulation arrangements include multiple encapsulation layers where a first encapsulation layer covers portions of a recess floor and sidewalls of the one or more LED chips, and a second encapsulation layer that covers the first encapsulation layer. In this manner, the first encapsulation layer is configured to buffer internal encapsulation stresses during operation that could lead to delamination of the LED chips.

In certain aspects, an LED package comprises: a housing that forms a recess with a recess floor and one or more recess sidewalls; a lead frame structure extending through the housing, wherein a portion of the lead frame structure is arranged along the recess floor; at least one LED chip arranged within the recess and electrically coupled with the lead frame structure; a first encapsulation layer arranged on the recess floor, on the portion of the lead frame structure that is arranged along the recess floor, and on one or more sidewalls of the at least one LED chip; and a second encapsulation layer arranged within the recess on the first encapsulation layer, wherein a weight percentage of the first encapsulation layer is less than 50% of a total encapsulation weight that is a sum of weights of the first encapsulation layer and the second encapsulation layer. In certain embodiments, the weight percentage of the first encapsulation layer is less than 25% of the total encapsulation weight. In certain embodiments, the weight percentage of the first encapsulation layer is in a range from 3% to 10% of the total encapsulation weight. In certain embodiments, the at least one LED chip is electrically connected to a portion of the lead frame structure with a wire bond, and a portion of the wire bond extends from the first encapsulation layer into the second encapsulation layer. In certain embodiments, the at least one LED chip is electrically connected to a portion of the lead frame structure with a wire bond, and a top surface of the first encapsulation layer forms an upward protrusion that is registered with the wire bond. In certain embodiments, the at least one LED chip comprises a plurality of LED chips and a first LED chip of the plurality of LED chips includes a top surface that resides within the second encapsulation layer. In certain embodiments, a top surface of the first encapsulation layer forms an upward protrusion that is registered with the at least one LED chip. In certain embodiments, the at least one LED chip comprises a first LED chip and a second LED chip, and a top surface of the first encapsulation layer between the first LED chip and the second LED chip is positioned at a height above the recess floor that is less than a height of the first LED chip and the second LED chip above the recess floor. In certain embodiments, the at least one LED chip comprises a first LED chip and a second LED chip, and the first encapsulation layer is on one or more sidewalls of the first LED chip without covering one or more sidewalls of the second LED chip. In certain embodiments, the first encapsulation layer and the second encapsulation layer comprise a same material. In certain embodiments, the first encapsulation layer covers a top surface of the at least one LED chip, and the top surface is positioned opposite the recess floor. The LED package may further comprise a curved lens on the second encapsulation layer. In certain embodiments, the second encapsulation layer forms a lens shape that is positioned above the recess.

In another aspect, an LED package comprises: a housing that forms a recess with a recess floor and one or more recess sidewalls; a lead frame structure extending through the housing, wherein a portion of the lead frame structure is arranged along the recess floor; at least one LED chip arranged within the recess and electrically coupled with the lead frame structure; a first encapsulation layer arranged on the recess floor, on the portion of the lead frame structure that is arranged along the recess floor, and on one or more sidewalls of the at least one LED chip, wherein the first encapsulation layer is conformal along the at least one LED chip such that a top surface of the first encapsulation layer forms an upward protrusion that is registered with the at least one LED chip; and a second encapsulation layer arranged within the recess on the first encapsulation layer. In certain embodiments, the first encapsulation layer and the second encapsulation layer comprise a same material. In certain embodiments, the first encapsulation layer covers a top surface of the at least one LED chip, and the top surface is positioned opposite the recess floor. In certain embodiments, the at least one LED chip is electrically connected to a portion of the lead frame structure with a wire bond, and a portion of the wire bond extends from the first encapsulation layer into the second encapsulation layer. In certain embodiments, the at least one LED chip is electrically connected to a portion of the lead frame structure with a wire bond and the upward protrusion is registered with the wire bond. In certain embodiments, the at least one LED chip comprises a first LED chip and a second LED chip, and a top surface of the first encapsulation layer between the first LED chip and the second LED chip is positioned at a height above the recess floor that is less than a height of the first LED chip and the second LED chip above the recess floor. The LED package may further comprise a curved lens on the second encapsulation layer. In certain embodiments, the second encapsulation layer forms a lens shape that is positioned above the recess.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of a light-emitting diode (LED) package that includes a lead frame structure collectively formed by a plurality of leads, a body or housing that encases a portion of the lead frame structure, and a first encapsulation layer that is arranged within a recess that is formed by the housing.

FIG. 1B is a cross-sectional view of the LED package of FIG. 1A taken along the sectional line 1B-1B of FIG. 1A.

FIG. 2 is a cross-sectional view of an LED package that is similar to the LED package of FIGS. 1A and 1B and illustrates an arrangement for the first encapsulation layer that covers the recess floor, the LED chips, and the wire bonds.

FIG. 3 is a cross-sectional view of an LED package that is similar to the LED package of FIG. 2 but with a reduced amount of the first encapsulation layer.

FIG. 4 is a cross-sectional view of an LED package that is similar to the LED package of FIG. 3 but with an even further reduced amount of the first encapsulation layer.

FIG. 5 is a cross-sectional view of an LED package that is similar to the LED package of FIG. 4 but with an even further reduced amount of the first encapsulation layer such that the first encapsulation layer only covers a portion of the recess floor.

FIG. 6A is a top view of an LED package that is similar to the LED package of FIG. 1A and includes an arrangement where the first encapsulation layer partially covers the recess floor.

FIG. 6B is a cross-sectional view of the LED package of FIG. 6A taken along the sectional line 6B-6B of FIG. 6A.

FIG. 7A is a top view of an LED package that is similar to the LED package of FIG. 6A and includes an arrangement where the first encapsulation layer partially covers more of the recess floor than in FIG. 6A.

FIG. 7B is a cross-sectional view of the LED package of FIG. 7A taken along the sectional line 7B-7B of FIG. 7A.

FIG. 8A is a top view of an LED package that is similar to the LED package of FIG. 7A and includes an arrangement where the first encapsulation layer partially covers almost all of the recess floor.

FIG. 8B is a cross-sectional view of the LED package of FIG. 8A taken along the sectional line 8B-8B of FIG. 8A.

FIG. 9 is a generalized cross-sectional view of an LED package that is similar to the LED package of FIGS. 1A and 1B except that the LED package is configured to house a single LED chip.

FIG. 10 is a generalized cross-sectional view of an LED package that is similar to the LED package of FIG. 9 and further includes a lens that is arranged over the recess.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) packages, and more particularly to encapsulation arrangements in LED packages that provide reduced internal stresses. LED packages may include housings that form a recess with one or more LED chips provided within the recess. Encapsulation arrangements include multiple encapsulation layers where a first encapsulation layer covers portions of a recess floor and sidewalls of the one or more LED chips, and a second encapsulation layer that covers the first encapsulation layer. In this manner, the first encapsulation layer is configured to buffer internal encapsulation stresses during operation that could lead to delamination of the LED chips.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), and GaN, with a suitable substrate being a 4H polytype of SiC, although other SiC polytypes can also be used including 3C, 6H, and 15R polytypes. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000 K. In certain embodiments, lumiphoric materials having cyan, green, amber, yellow, orange, and/or red peak wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) may be coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others, that are provided with one or more LED chips. In certain aspects, an LED package may include a support member, such as a submount or a lead frame. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. In still further embodiments, the support structure may embody a lead frame structure. Light-altering materials may be arranged within LED packages to reflect or otherwise redirect light from the one or more LED chips in a desired emission direction or pattern.

In certain embodiments, aspects of the present disclosure relate to encapsulation arrangements in LED packages, and more particularly to LED packages with lead frame structures that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

Conventional encapsulation materials for such LED packages are typically provided by a single dispensing process that fills the recess in bulk and covers the LED chips within the recess. After dispensing, the encapsulation materials are typically cured. The curing process can introduce stress build-up within the encapsulation material due to shrinkage associated with curing. Similar stresses can also be introduced during other reliability testing the LED package may be subjected to, such as high temperature and high humidity storage testing, and thermal testing, among others. Additionally, stresses can continue to build over time while the LED package is in use due to thermal cycling and/or other environmental operating conditions. During operation, such internal package stresses can cause the package housing and the encapsulation material to flex. Since the housing and the encapsulation material are formed of different materials with different coefficients of thermal expansion, the flexing of the housing can cause stress in the encapsulation material in a direction toward the LED chips at the bottom of the recess. Over time, the stress can cause the encapsulation material to separate from the bottom of the recess. When the encapsulation material separates in this manner, the encapsulation material may exert a sufficient force to cause delamination of the LED chips and/or the encapsulation material from the lead frame structure. In this regard, electrical connections between the LED chips and the lead frame structure may be severed, thereby causing catastrophic failure of the LED package. Other associated failure modes may include wire bond failures or performance degradation related to reduced thermal contact between the LED chips and the lead frame structure.

According to principles of the present disclosure, encapsulation arrangements include multiple layer encapsulation structures where a first encapsulation layer is formed within the package recess to cover portions of a recess floor and/or portions of the LED chips at the recess floor, followed by a second encapsulation layer that is formed in the recess and on the first encapsulation layer. The first encapsulation layer may be cured or partially cured before the second encapsulation layer is formed and cured. In the case of partial curing of the first encapsulation layer, additional curing may be provided concurrently with the curing of the second encapsulation layer. The first encapsulation layer may conformally cover portions of the recess floor, portions of recess sidewalls, and portions of LED chips. The second encapsulation layer may then fill the remainder of the recess. In this manner, stresses associated with curing and/or operating conditions of the LED package may exert a stress on the second encapsulation layer that may be absorbed or otherwise buffered by the first encapsulation layer before causing LED chip delamination.

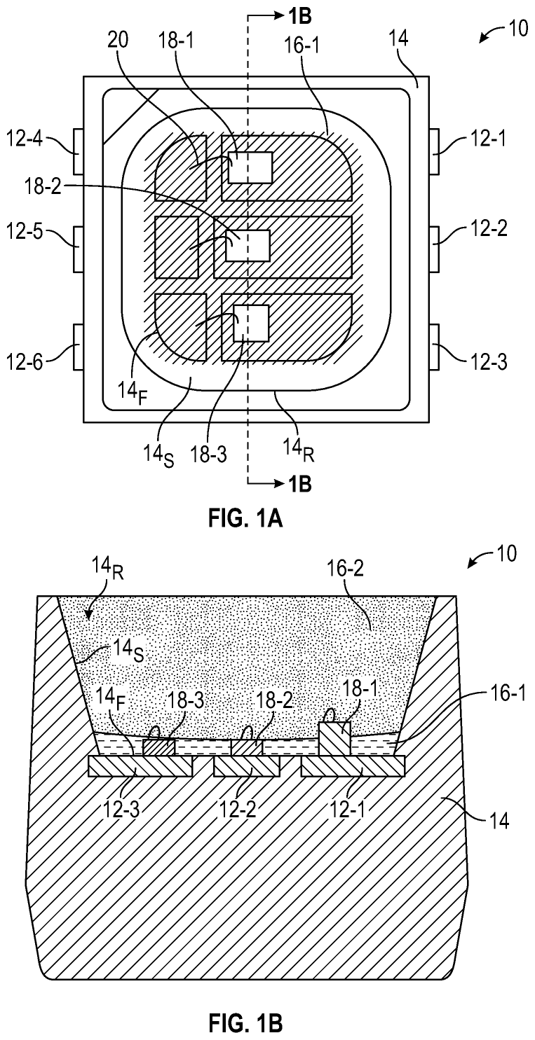

FIG. 1A is a top view of an LED package 10 that includes a lead frame structure collectively formed by a plurality of leads 12-1 to 12-6, a body or housing 14 that encases a portion of the lead frame structure, and a first encapsulation layer 16-1 that is arranged within a recess 14R that is formed by the housing 14. FIG. 1B is a cross-sectional view of the LED package 10 of FIG. 1 A taken along the sectional line 1B-1B of FIG. 1A. The LED package 10 includes LED chips 18-1 to 18-3 that are mounted on and electrically respectively coupled to the leads 12-1 to 12-3 and electrically coupled to corresponding leads 12-4 to 12-6 by way of wire bonds 20. While a single wire bond 20 is illustrated for each LED chip 18-1 to 18-3, it is understood that various ones of the LED chip 18-1 to 18-3 may embody a lateral structure where a second wire bond may be employed to provide electrical coupling.

In certain aspects, each of the LED chips 18-1 to 18-3 may be configured to emit a different wavelength from the other LED chips. For example, the LED chip 18-1 may be configured to emit red light, the LED chip 18-2 may be configured to emit green light, and the LED chip 18-3 may be configured to emit blue light. In certain embodiments, differences between red, green, and blue emissions may necessitate the the LED chip 18-1 being formed of a different material system than the other LED chips 18-2, 18-3. In still further embodiments, the differences between the LED chips 18-1 to 18-3 may include different chip geometries, such as the LED chip 18-1 having a greater thickness than the LED chips 18-2, 18-3. While three LED chips 18-1 to 18-3 are illustrated, the principles disclosed herein are applicable to any number of LED chips within the LED package 10. The recess 14R may include a recess floor 14_{F} and one or more recess sidewalls 14_{S}. The leads 12-1 to 12-6 may be arranged to extend through the housing 14 and a portion of the leads 12-1 to 12-6 may be arranged along or otherwise exposed at the recess floor 14_{F}.

As best illustrated in FIG. 1B, the first encapsulation layer 16-1 may be arranged on portions of the one or more recess sidewalls 14_{S}, along the recess floor 14_{F}, and covering portions of the leads 12-1 to 12-6 that are arranged along the recess floor 14_{F}. Depending on various geometries of the LED chips 18-1 to 18-3, the first encapsulation layer 16-1 may cover one or more sidewalls of the LED chips 18-1 to 18-3, as well as some top surfaces of the LED chips 18-1 to 18-3. For example, one or more portions of the LED chip 18-1 may extend above top surfaces of the first encapsulation layer 16-1. The first encapsulation layer 16-1 may include an epoxy or silicone, depending on the application. A second encapsulation layer 16-2, which may also include silicone or epoxy, may fill the remainder of the recess 14_{R} above the first encapsulation layer 16-1. In certain aspects, both the first encapsulation layer 16-1 and the second encapsulation layer 16-2 may comprise a same material with same optical properties. For example, both encapsulation layers 16-1, 16-2 may include epoxy. In further embodiments, both encapsulation layers 16-1, 16-2 may be configured to be light-transmissive and/or light-transparent to wavelengths of light generated by the LED chips 18-1 to 18-3. In the example where the LED chip 18-1 extends above the first encapsulation layer 16-1, one or more portions of the LED chip 18-1, such as a top surface of the LED chip 18-1 may extend into or otherwise reside within the second encapsulation layer 16-2.

The first encapsulation layer 16-1 may be dispensed within the recess 14_{R} and around one or more of the LED chips 18-1 to 18-3. In certain embodiments, the first encapsulation layer 16-1 may be allowed to settle within the recess 14_{R} for a time period at an elevated temperature, but below a curing temperature for the first encapsulation layer 16-1. After settling, the first encapsulation layer 16-1 may be subjected to a first curing step. The curing may involve a full cure or a partial cure of the first encapsulation layer 16-1. Parameters for the curing step for the first encapsulation layer 16-1 may be varied based on a desired arrangement for stress mitigation. Such parameters may include lower curing temperatures, slowing temperature ramping during curing, shorter curing times at hotter temperatures, and longer curing times at lower temperatures. The second encapsulation layer 16-2 may then be formed over the first encapsulation layer 16-1 and a second curing step may be performed to cure the second encapsulation layer 16-2. In certain embodiments, portions of the first encapsulation layer 16-1 that were not fully cured in the first curing step may be cured by the second step. In this regard, encapsulation for the LED package 10 may be provided by a multiple-step process. The presence of the first encapsulation layer 16-1 that covers the recess floor 14_{F} and portions of the LED chips 18-1 to 18-3 effectively forms a buffer for stress that may be present in the second encapsulation layer 16-2 due to curing shrinkage and/or operating conditions of the LED package 10. In this manner, the stress profile of the LED package 10 may be redistributed such that delamination of the LED chips 18-1 to 18-3 is avoided.

Relative amounts of first and second encapsulation layers 16-1 to 16-2 may be tailored to accommodate stresses in different LED package sizes and/or layouts. For example, in certain embodiments, a weight percentage of the first encapsulation layer 16-1 may be less than or equal to 50% of a total encapsulation weight. As used herein, a total encapsulation weight includes all encapsulation layers that may be present within the recess 14_{R}. In the context of FIG. 1B, the total encapsulation weight would include both the first encapsulation layer 16-1 and the second encapsulation layer 16-2. If additional encapsulation layers were present in the recess 14_{R}, then the total encapsulation weight would include the first encapsulation layer 16-1, the second encapsulation layer 16-2, and the additional encapsulation layers. Depending on the package geometry, if the weight percentage of the first encapsulation layer 16-1 exceeds 50% of the total encapsulation weight, the stress mitigation benefits described above may be reduced. In certain package geometries, the first encapsulation layer 16-1 may be provided in smaller amounts, such as a weight percentage of less than or equal to 40%, or less than or equal to 25%, or less than or equal to 15%, or less than or equal to 10%, or in a range from 3% to 10% of the total encapsulation weight within the recess 14_{R}. In general, smaller size LED packages with smaller and/or shallower recesses 14_{R} may include higher weight percentages for the first encapsulation layer 16-1 to provide similar stress mitigation as larger size LED packages with larger and/or deeper recesses 14_{R}. While the second encapsulation layer 16-2 is illustrated as generally flat at a top of the recess 14_{R}, other embodiments may include other shapes, such as a curved lens that extends above the recess 14_{R}, or a separate lens that is affixed to the second encapsulation layer 16-2.

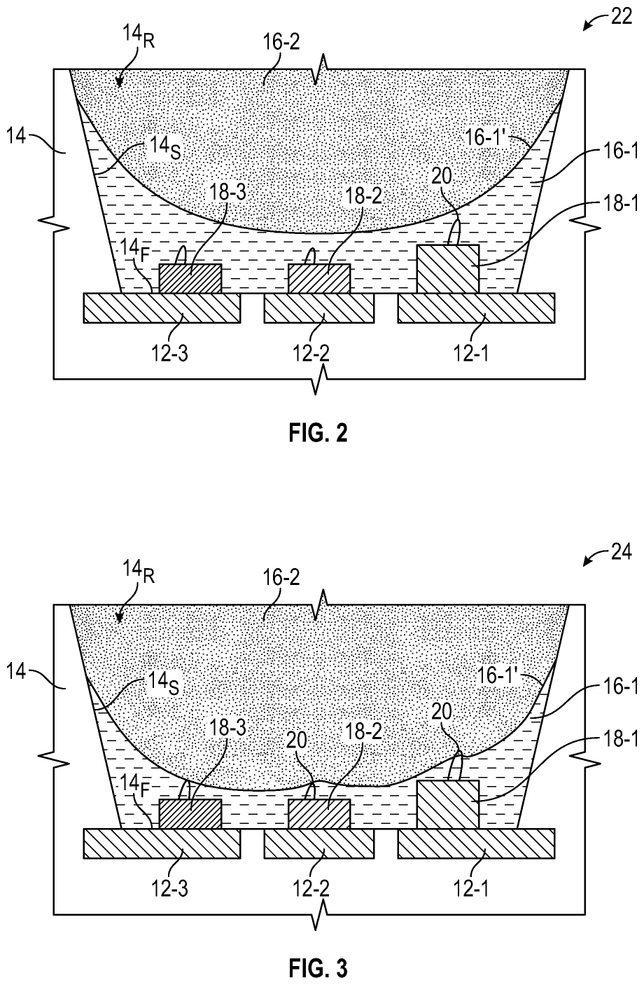

FIG. 2 is a cross-sectional view of an LED package 22 that is similar to the LED package 10 of FIGS. 1A and 1B and illustrates an arrangement for the first encapsulation layer 16-1 that covers the recess floor 14_{F}, the LED chips 18-1 to 18-3, and the wire bonds 20. As illustrated, a profile of a top surface 16-1′ of the first encapsulation layer 16-1 is generally curved in a direction toward the recess floor 14_{F}, and the first encapsulation layer 16-1 covers portions of the recess sidewalls 14_{S} almost to a top of the recess 14_{R}. This arrangement of the first encapsulation layer 16-1 also covers top surfaces of the LED chips 18-1 to 18-3, wherein the top surfaces are positioned opposite the recess floor 14_{F}. Such a configuration may involve a weight percentage of the first encapsulation layer 16-1 that is in a range from 35% to 50%, or in a range from 35% to 45%. For this package geometry, such a weight percentage may provide improved stress relief to avoid delamination. However, increases in the weight percentage of the first encapsulation layer 16-1 above 50% may result in diminishing benefits since stress in the first encapsulation layer 16-1 covers a large volume within the recess 14_{R} and could lead to delamination of the LED chips 18-1 to 18-3 from the leads 12-1 to 12-3. While the second encapsulation layer 16-2 is illustrated as generally flat at a top of the recess 14_{R}, other embodiments may include other shapes, such as a curved lens that extends above the recess 14_{R}, or a separate lens that is affixed to the second encapsulation layer 16-2.

FIG. 3 is a cross-sectional view of an LED package 24 that is similar to the LED package 22 of FIG. 2 but with a reduced amount of the first encapsulation layer 16-1. In FIG. 3, the weight percentage of the first encapsulation layer 16-1 is in a range from 15% to 25% of the total encapsulation weight within the recess 14_{R}. Accordingly, the amount of the first encapsulation layer 16-1 is farther away from an amount that would result in diminishing benefits for stress relief. Notably, the top surface 16-1′ of the first encapsulation layer 16-1 is conformal along the wire bonds 20 such that upward protrusions of the first encapsulation layer 16-1 are registered with one or more of the wire bonds 20. As used herein, an upward protrusion of the first encapsulation layer 16-1 is associated with a contour of the top surface 16-1′ that follows a contour of one or more of the LED chips (e.g., 18-1 and 18-2 in FIG. 3) and/or wire bonds 20 relative to the recess floor 14_{F}. In certain embodiments, one or more of the wire bonds 20, such as the one associated with the LED chip 18-1, may protrude above the first encapsulation layer 16-1 to extend into the second encapsulation layer 16-2. Additionally, other wire bonds 20, such as those associated with the LED chips 18-2, 18-3, may reside entirely within the first encapsulation layer 16-2. In a similar manner to FIG. 2, the arrangement of the first encapsulation layer 16-1 in FIG. 3 covers top surfaces of the LED chips 18-1 to 18-3, wherein the top surfaces are positioned opposite the recess floor 14_{F}. As with other embodiments, the second encapsulation layer 16-2 may include other shapes, such as a curved lens that extends above the recess 14_{R}, or a separate lens that is affixed to the second encapsulation layer 16-2.

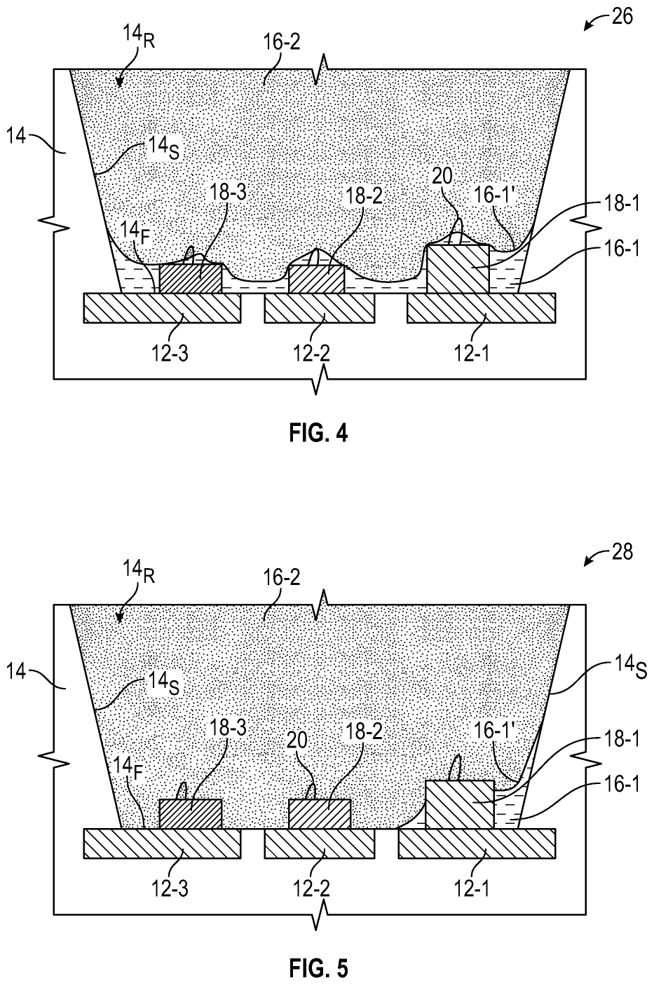

FIG. 4 is a cross-sectional view of an LED package 26 that is similar to the LED package 24 of FIG. 3 but with an even further reduced amount of the first encapsulation layer 16-1. In FIG. 4, the weight percentage of the first encapsulation layer 16-1 is in a range from 5% to 10% of the total encapsulation weight within the recess 14_{R}. Accordingly, the amount of the first encapsulation layer 16-1 is even farther away from an amount that would result in diminishing benefits for stress relief. Notably, the top surface 16-1′ of the first encapsulation layer 16-1 is conformal along the wire bonds 20 such that upward protrusions of the first encapsulation layer 16-1 are registered with one or more of the wire bonds 20. In certain aspects, upward protrusions of the first encapsulation layer 16-1 are registered with each of the LED chips 18-1 to 18-3. In this manner, in positions that are between neighboring ones of the LED chips 18-1 to 18-3, the top surface 16-1′ of the first encapsulation layer 16-1 may reside at a height above the recess floor 14_{F} that is below a height of the LED chips 18-1 to 18-3 above the recess floor 14_{F}. In certain aspects, the arrangement of the first encapsulation layer 16-1 may suitably cover the recess floor 14_{F}, sidewalls of the LED chips 18-1 to 18-3, and one or more top surfaces of the LED chips 18-1 to 18-3 while still occupying the reduced weight percentage. In this regard, the arrangement of the first encapsulation layer 16-1 may provide improved stress mitigation in a more repeatable manner as compared with arrangements where the weight percentage of the first encapsulation layer 16-1 is closer to percentages that exhibit diminishing stress relief. As with other embodiments, the second encapsulation layer 16-2 may include other shapes, such as a curved lens that extends above the recess 14_{R}, or a separate lens that is affixed to the second encapsulation layer 16-2.

FIG. 5 is a cross-sectional view of an LED package 28 that is similar to the LED package 26 of FIG. 4 but with an even further reduced amount of the first encapsulation layer 16-1 such that the first encapsulation layer 16-1 only covers a portion of the recess floor 14_{F}. As illustrated, the first encapsulation layer 16-1 is arranged to cover sidewall portions of the first LED chip 18-1 and adjacent portions of the recess floor 14_{F} without entirely covering the recess floor 14_{F} near the other LED chips 18-2, 18-3. In this manner, the weight percentage of the first encapsulation layer 16-1 may be provided in a range from 1% to 5% of the total encapsulation weight within the recess 14_{R}. Such an arrangement may be beneficial for mitigating stress for certain LED chips (e.g., 18-1 in FIG. 5) that may be more prone to delamination. For example, the LED chip 18-1 may include a greater height above the recess floor 14_{F} than the other LED chips 18-2, 18-3 such that the LED chip 18-1 may be more sensitive to encapsulation stresses described above. By providing the first encapsulation layer 16-1 proximate the first LED chip 18-1, such stresses may be mitigated to reduce instances of delamination. Notably, the LED chip 18-1 is arranged proximate one of the recess sidewalls 14_{S} such that the low weight percentage may still provide an arrangement of the first encapsulation layer 16-1 that extends along the recess sidewall 14_{S} in a position that is above a height of the LED chip 18-1. Accordingly, a small amount of the first encapsulation layer 16-1 may be sufficient for absorbing stress and preventing delamination of the first LED chip 18-1. In certain aspects, the height differences may be related to the LED chip 18-1 being formed of a different material system for emitting a different wavelength of light, such as red, than the other LED chips 18-2, 18-3, which may be configured to emit blue and/or green light.

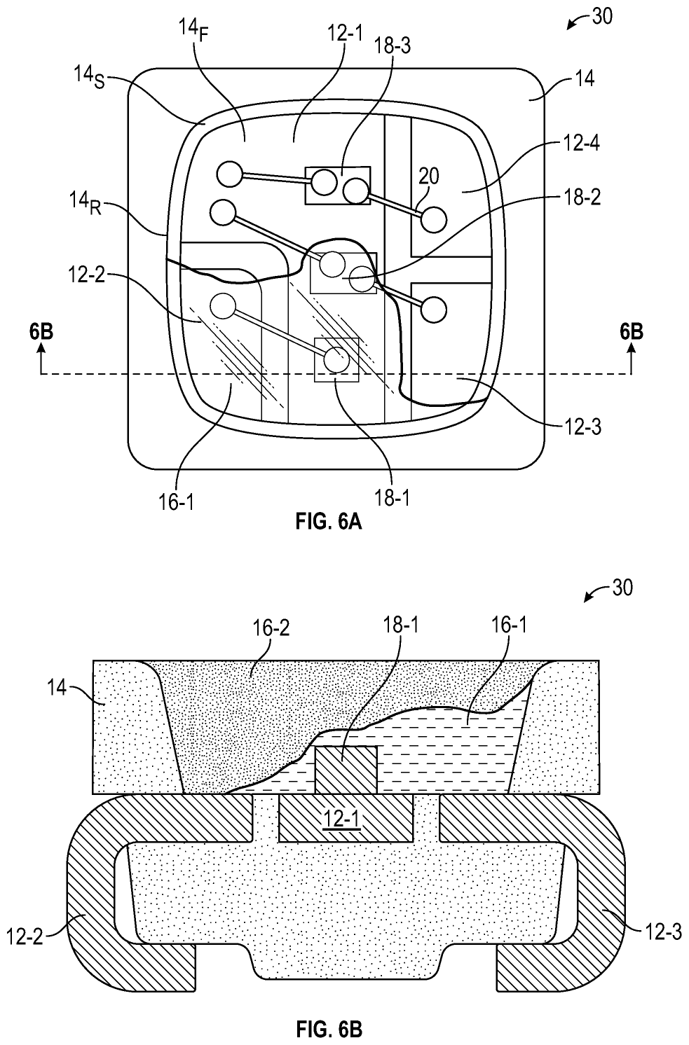

FIG. 6A is a top view of an LED package 30 that is similar to the LED package 10 of FIG. 1A and includes an arrangement where the first encapsulation layer 16-1 partially covers the recess floor 14_{F}. FIG. 6B is a cross-sectional view of the LED package 30 of FIG. 6A taken along the sectional line 6B-6B of FIG. 6A. While not drawn to scale, the LED package 30 may have smaller overall dimensions than the LED package 10 of FIG. 1A. As such, the relative size of the recess 14_{R} in the LED package 30 is smaller than the corresponding recess 14_{R} of the LED package 10 of FIG. 1A. In this regard, relative amounts of the first encapsulation layer 16-1 may be different than the LED package 10 of FIG. 1A to provide suitable stress mitigation. Nonetheless, the weight percentages and weight percentage ranges described above are still applicable for the LED package 30 depending on how many of the LED chips 18-1 to 18-3 require stress mitigation. In certain embodiments, each of the LED chips 18-1 to 18-3 may be mounted on and electrically coupled to the common lead 12-1, while being separately electrically coupled to different ones of the other leads 12-2 to 12-4. As illustrated, the first encapsulation layer 16-1 is arranged on portions of the recess floor 14_{F} that are proximate the first LED chip 18-1, and a portion of the first encapsulation layer 16-1 extends to the second LED chip 18-2. In this manner, a bulk of the first encapsulation layer 16-1 is provided along sidewalls of the first LED chip 18-1, along portions of the recess floor 14_{F} that are proximate the first LED chip 18-1, and along portions of recess sidewalls 14_{S} that are proximate the first LED chip 18-1. Such an arrangement may be useful for embodiments where the first LED chip 18-1 is more prone to delamination due to encapsulation stresses.

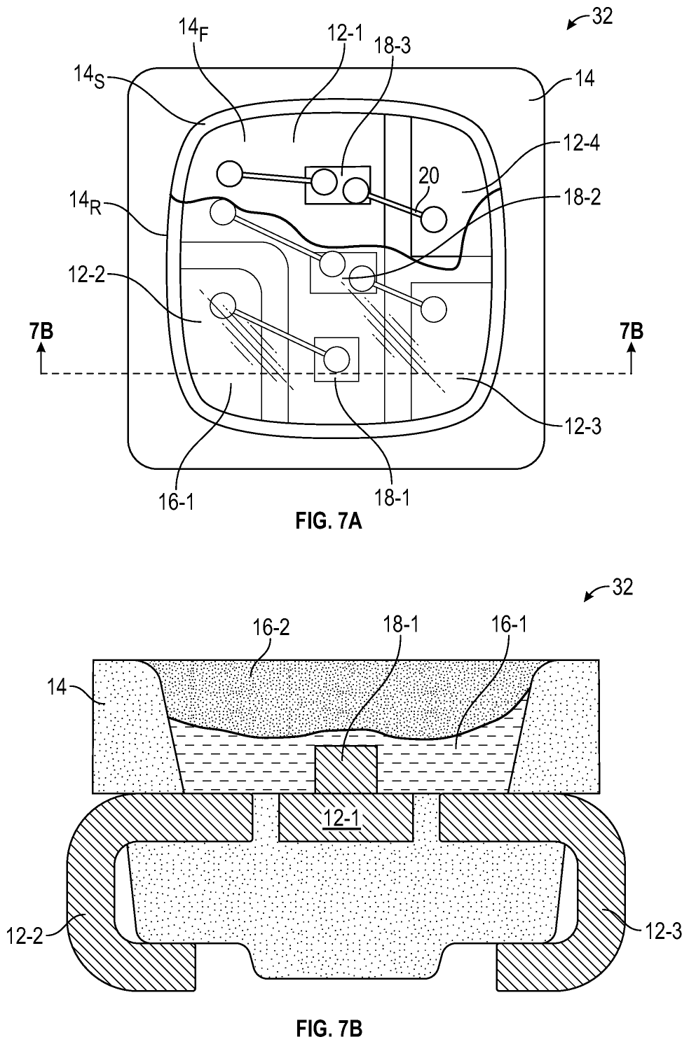

FIG. 7A is a top view of an LED package 32 that is similar to the LED package 30 of FIG. 6A and includes an arrangement where the first encapsulation layer 16-1 partially covers more of the recess floor 14_{F} than in FIG. 6A. FIG. 7B is a cross-sectional view of the LED package 32 of FIG. 7A taken along the sectional line 7B-7B of FIG. 7A. As illustrated, the first encapsulation layer 16-1 is arranged on portions of the recess floor 14_{F} that are proximate the first LED chip 18-1 and the second LED chip 18-2. In this manner, a bulk of the first encapsulation layer 16-1 is provided along sidewalls of the first and second LED chips 18-1,18-2, along portions of the recess floor 14_{F} that are proximate the first and second LED chips 18-1,18-2, and along portions of recess sidewalls 14_{S} that are proximate the first and second LED chips 18-1,18-2. Such an arrangement may be useful for embodiments where the first LED chip 18-1 and the second LED chip 18-2 are more prone to delamination due to encapsulation stresses than the third LED chip 18-3.

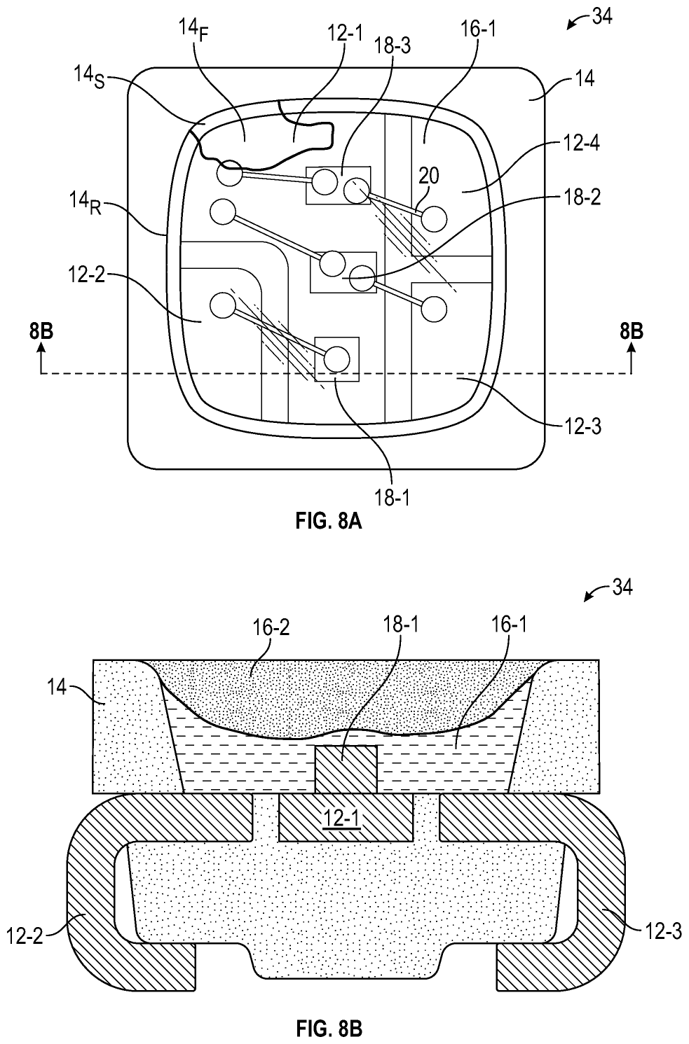

FIG. 8A is a top view of an LED package 34 that is similar to the LED package 32 of FIG. 7A and includes an arrangement where the first encapsulation layer 16-1 partially covers almost all of the recess floor 14_{F}. FIG. 8B is a cross-sectional view of the LED package 34 of FIG. 8A taken along the sectional line 8B-8B of FIG. 8A. As illustrated, the first encapsulation layer 16-1 is arranged on portions of the recess floor 14_{F} that are proximate all the LED chips 18-1 to 18-3. In certain embodiments, relative amounts of the first encapsulation layer 16-1 may be greater proximate the first LED chip 18-1 than the third chip 18-3. In this manner, extra stress mitigation may be provided for the first LED chip 18-1, while suitable stress mitigation is provided for the second and third LED chips 18-2, 18-3.

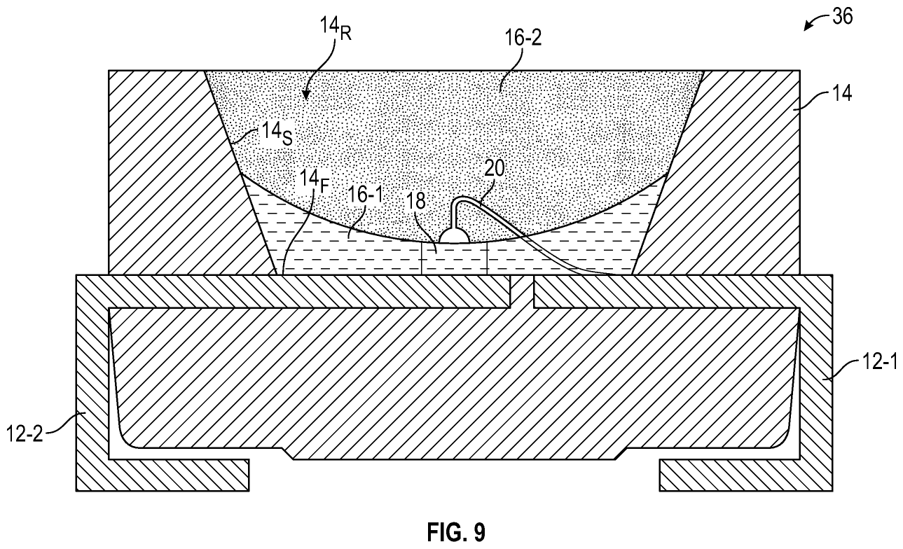

FIG. 9 is a generalized cross-sectional view of an LED package 36 that is similar to the LED package 10 of FIGS. 1A and 1B except that the LED package 36 is configured to house a single LED chip 18. While not drawn to scale, the LED package 36 may have smaller overall dimensions than the LED package 10 of FIG. 1A. As such, the relative size of the recess 14_{R} in the LED package 36 is smaller than the corresponding recess 14_{R} of the LED package 10 of FIG. 1A. In this regard, relative amounts of the first encapsulation layer 16-1 may be different than the LED package 10 of FIG. 1A to provide suitable stress mitigation for the LED chip 18. For example, in certain embodiments, the weight percentage of the first encapsulation layer 16-1 is in a range from 30% to 70%, or in a range from 40% to 60% of the total encapsulation weight within the recess 14_{R} in order to provide suitable coverage of the sidewalls of the LED chip 18 and the recess floor 14_{F}.

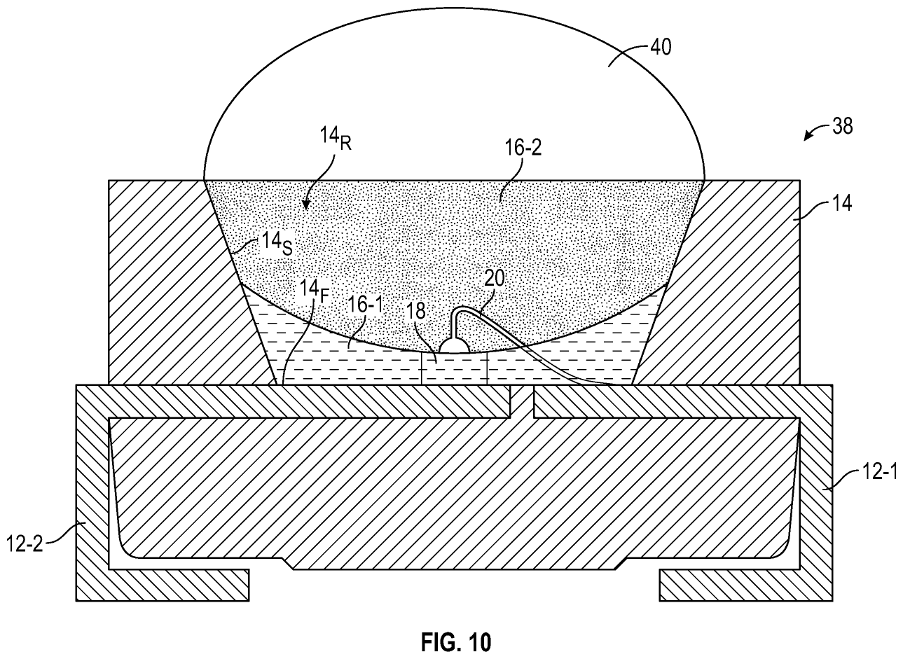

FIG. 10 is a generalized cross-sectional view of an LED package 38 that is similar to the LED package 36 of FIG. 9 and further includes a lens 40 that is arranged over the recess 14_{R}. In certain embodiments, the lens 40 may be formed by portions of the second encapsulation layer 16-2 that extend out from the recess 14_{R} and are molded to form a shape of a lens, such as a curved lens that extends above the recess 14_{R}. While the lens 40 may form a generally hemispherical shape, other shapes, such as an oval, ellipsoid bullet, hex-shaped, square or cube shaped, and shapes that have both curved and planar surfaces are also possible. In still further embodiments, the lens 40 may be formed as a separate element that is affixed to the second encapsulation layer 16-2. While the lens 40 is illustrated in the context of FIG. 10, the lens 40 described herein may be present in any of the previously described embodiments, including those illustrated in any of FIGS. 1A to FIG. 9.

As described herein, multiple-step and/or multiple-layer encapsulation structures are disclosed that provide reduced internal stresses during operation for reducing instances of LED chip delamination. In various aspects, the encapsulation structures may be formed with materials that are the same or visually similar to an observer. However, interfaces between individual layers of the encapsulation structures are readily visible from microscopic cross-sectional images, including images obtained by an optical microscope or a scanning electron microscope (SEM), among others. In certain aspects, the multiple-layer encapsulation structures may be formed with same or similar optical characteristics to provide a similar optical performance compared to conventional single-layer encapsulation structures. In this regard, the multiple-layer encapsulation structures may be formed such that each layer of the structure is configured with a same or similar light-transmissivity and/or light-transparency for light from the LED chip.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a housing that forms a recess with a recess floor and one or more recess sidewalls;
a lead frame structure extending through the housing, wherein a portion of the lead frame structure is arranged along the recess floor;
at least one LED chip arranged within the recess and electrically coupled with the lead frame structure;
a first encapsulation layer arranged on the recess floor, on the portion of the lead frame structure that is arranged along the recess floor, and on one or more sidewalls of the at least one LED chip; and
a second encapsulation layer arranged within the recess on the first encapsulation layer, wherein a weight percentage of the first encapsulation layer is less than 50% of a total encapsulation weight that is a sum of weights of the first encapsulation layer and the second encapsulation layer.

2. The LED package of claim 1, wherein the weight percentage of the first encapsulation layer is less than 25% of the total encapsulation weight.

3. The LED package of claim 1, wherein the weight percentage of the first encapsulation layer is in a range from 3% to 10% of the total encapsulation weight.

4. The LED package of claim 1, wherein the at least one LED chip is electrically connected to a portion of the lead frame structure with a wire bond, and a portion of the wire bond extends from the first encapsulation layer into the second encapsulation layer.

5. The LED package of claim 1, wherein the at least one LED chip is electrically connected to a portion of the lead frame structure with a wire bond, and a top surface of the first encapsulation layer forms an upward protrusion that is registered with the wire bond.

6. The LED package of claim 1, wherein the at least one LED chip comprises a plurality of LED chips and a first LED chip of the plurality of LED chips includes a top surface that resides within the second encapsulation layer.

7. The LED package of claim 1, wherein a top surface of the first encapsulation layer forms an upward protrusion that is registered with the at least one LED chip.

8. The LED package of claim 1, wherein the at least one LED chip comprises a first LED chip and a second LED chip, and a top surface of the first encapsulation layer between the first LED chip and the second LED chip is positioned at a height above the recess floor that is less than a height of the first LED chip and the second LED chip above the recess floor.

9. The LED package of claim 1, wherein the at least one LED chip comprises a first LED chip and a second LED chip, and the first encapsulation layer is on one or more sidewalls of the first LED chip without covering one or more sidewalls of the second LED chip.

10. The LED package of claim 1, wherein the first encapsulation layer and the second encapsulation layer comprise a same material.

11. The LED package of claim 1, wherein the first encapsulation layer covers a top surface of the at least one LED chip, and the top surface is positioned opposite the recess floor.

12. The LED package of claim 1, further comprising a curved lens on the second encapsulation layer.

13. The LED package of claim 1, wherein the second encapsulation layer forms a lens shape that is positioned above the recess.

14. A light-emitting diode (LED) package comprising:
a housing that forms a recess with a recess floor and one or more recess sidewalls;
a lead frame structure extending through the housing, wherein a portion of the lead frame structure is arranged along the recess floor;
at least one LED chip arranged within the recess and electrically coupled with the lead frame structure;
a first encapsulation layer arranged on the recess floor, on the portion of the lead frame structure that is arranged along the recess floor, and on one or more sidewalls of the at least one LED chip, wherein the first encapsulation layer is conformal along the at least one LED chip such that a top surface of the first encapsulation layer forms an upward protrusion that is registered with the at least one LED chip; and
a second encapsulation layer arranged within the recess on the first encapsulation layer.

15. The LED package of claim 14, wherein the first encapsulation layer and the second encapsulation layer comprise a same material.

16. The LED package of claim 14, wherein the first encapsulation layer covers a top surface of the at least one LED chip, and the top surface is positioned opposite the recess floor.

17. The LED package of claim 14, wherein the at least one LED chip is electrically connected to a portion of the lead frame structure with a wire bond, and a portion of the wire bond extends from the first encapsulation layer into the second encapsulation layer.

18. The LED package of claim 14, wherein the at least one LED chip is electrically connected to a portion of the lead frame structure with a wire bond and the upward protrusion is registered with the wire bond.

19. The LED package of claim 14, wherein the at least one LED chip comprises a first LED chip and a second LED chip, and a top surface of the first encapsulation layer between the first LED chip and the second LED chip is positioned at a height above the recess floor that is less than a height of the first LED chip and the second LED chip above the recess floor.

20. The LED package of claim 14, further comprising a curved lens on the second encapsulation layer.

21. The LED package of claim 14, wherein the second encapsulation layer forms a lens shape that is positioned above the recess.
